(19) United States
(12) Patent Application Publication
(10) Pub. No.: US 2026/0205151 A1
(43) Pub. Date: Jul. 16, 2026

(54) TRANSCEIVER INCLUDING MODEM-BASED INFORMATION RECEIVER FILTER BYPASS FOR FREQUENCY DIVISION DUPLEXING

(71) Applicant: QUALCOMM Incorporated, San Diego, CA (US)

(72) Inventors: Erwin SPITS, Utrecht (NL); Francesco GATTA, San Diego, CA (US); Ryan Scott Castro SPRING, San Diego, CA (US); Harish VENKATACHARI, San Jose, CA (US); Valibabu SALADI, San Diego, CA (US)

(21) Appl. No.: 19/016,876

(22) Filed: Jan. 10, 2025

(51) Int. Cl. H04B 1/40; H04W 72/0446

(52) U.S. Cl. CPC H04B 1/40; H04W 72/0446; H03F 2200/294; H03F 2200/451

(57) ABSTRACT

An transceiver, including: a transmitter configured to transmit a first signal; a receiver configured to receive a second signal, wherein the receiver comprises: a filter; a low noise amplifier (LNA); a set of one or more switching devices configured to: route the second signal to the LNA via the filter based on a first state of a control signal, wherein the filter substantially prevents a leaked portion of the first signal from reaching the LNA; or route the second signal to the LNA while bypassing the filter based on a second state of the control signal; and a modem configured to generate the control signal.

### FIELD

This disclosure relates generally to transceivers, and in particular, to a transceiver including modem-based information receiver filter bypass for frequency division duplexing (FDD).

### BACKGROUND

A transceiver may wirelessly communicate with other devices using frequency division duplexing (FDD). In accordance with FDD, the transceiver includes: a transmitter configured to transmit a first signal within a first frequency band, and a receiver configured to receive a second signal within a second frequency band, wherein the first frequency band does not overlap in frequency with the second frequency band. Because of the non-overlapping frequency bands, the transmitter may transmit the first signal at the same time as the receiver receives the second signal. However, a portion of the first signal may leak into the receiver impacting the receiving and processing of the second signal.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a transceiver. The transceiver includes a transmitter configured to transmit a first signal; a receiver configured to receive a second signal, wherein the receiver comprises: a filter; a low noise amplifier (LNA); a set of one or more switching devices configured to: route the second signal to the LNA via the filter based on a first state of a control signal, wherein the filter substantially prevents a leaked portion of the first signal from reaching the LNA; or route the second signal to the LNA while bypassing the filter based on a second state of the control signal; and a modem configured to generate the control signal based on scheduling information associated with the transmission of the first signal.

Another aspect of the disclosure relates to a method. The method includes transmitting a first signal; receiving a second signal; routing the second signal to a low noise amplifier (LNA) via a filter based on a first state of a control signal, wherein the filter substantially prevents a leaked portion of the first signal from reaching the LNA; or routing the second signal to the LNA while bypassing the filter based on a second state of the control signal.

Another aspect of the disclosure relates to a transceiver. The transceiver includes means for transmitting a first signal; means for receiving a second signal; means for routing the second signal to a low noise amplifier (LNA) via a filter based on a first state of a control signal, wherein the filter substantially prevents a leaked portion of the first signal from reaching the LNA; or means for routing the second signal to the LNA while bypassing the filter based on a second state of the control signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example wireless communication system in accordance with an aspect of the disclosure.

FIG. 2A illustrates a block diagram of an example transceiver in accordance with another aspect of the disclosure.

FIG. 2B illustrates a timing diagram related to an example operation of the transceiver of FIG. 2A in accordance with another aspect of the disclosure.

FIG. 3A illustrates a block diagram of another example transceiver in accordance with another aspect of the disclosure.

FIG. 3B illustrates a timing diagram related to another example operation of the transceiver of FIG. 3A in accordance with another aspect of the disclosure.

FIG. 4 illustrates a block diagram of an example transceiver front-end in accordance with another aspect of the disclosure.

FIG. 5 illustrates a block diagram of another example transceiver radio frequency front-end (RFFE) in accordance with another aspect of the disclosure.

FIG. 6 illustrates a block diagram of another example transceiver radio frequency front-end (RFFE) in accordance with another aspect of the disclosure.

FIG. 7 illustrates a flow diagram of an example method of receiving a radio frequency (RF) signal in with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

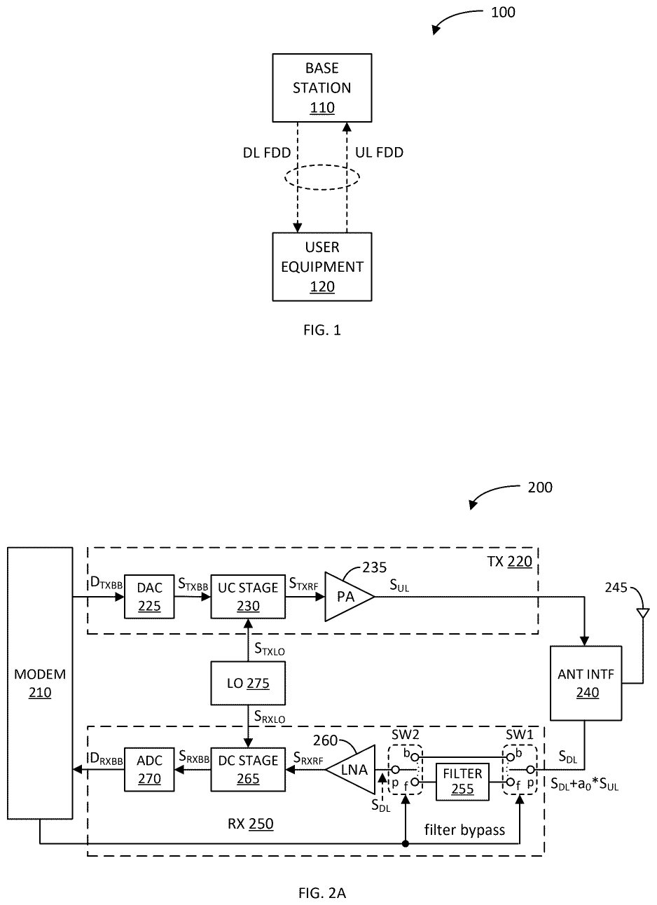

FIG. 1 illustrates a block diagram of an example wireless communication system 100 in accordance with an aspect of the disclosure. The wireless communication system 100 includes a base station (BS) 110 and a user equipment (UE) 120. The wireless communication system 100 may correspond to a wireless wide area network (WWAN) (e.g., a Fifth Generation (5G) or Sixth Generation (6G) New Radio (NR) WWAN or other), wireless local area network (WLAN) (e.g., WiFi or other), short range wireless area network (e.g., Bluetooth or other), a wireless personal area network (WPAN)), and/or other type of wireless network.

In this example, the base station (BS) 110 and the user equipment (UE) 120 wirelessly communicate with each other in accordance with frequency division duplexing (FDD). For example, the base station (BS) 110 may transmit a downlink (DL) FDD radio frequency (RF) signal within a first frequency band to the user equipment (UE) 120. The user equipment (UE) 120, in turn, may transmit an uplink (UL) FDD RF signal within a second frequency band to the base station (BS) 110. In accordance with FDD, the first and second frequency bands may be non-overlapping in frequency.

As the first and second frequency bands may be non-overlapping, the transmission of the DL FDD RF signal from the base station (BS) 110 to the user equipment (UE) 120 may occur simultaneous with or at the same time as the transmission of the UL FDD RF signal from the user equipment (UE) 120 to the base station (BS) 110. For example, with regard to the user equipment (UE) 120, it may employ a transceiver including a transmitter configured to transmit the UL FDD RF signal, and a receiver configured to receive the DL FDD RF signal. The receiver may include a filter to substantially filter out or block the UL FDD RF signal transmitted by the transmitter so as not to adversely impact the processing of the received DL FDD RF by the receiver. This is sometimes referred to as transceiver self-interference, which is explained in more detail with reference to the following discussion with respect to an exemplary transceiver.

FIG. 2A illustrates a block diagram of an example transceiver 200 in accordance with another aspect of the disclosure. The transceiver 200 may be implemented in the user equipment (UE) 120 for transmission of the UL FDD RF signal and reception of the DL FDD RF signal.

In particular, the transceiver 200 includes a modem 210, a transmitter 220, an antenna interface 240, an antenna (e.g., an antenna array) 245, a receiver 250, and a local oscillator (LO) 275. The transmitter 220, in turn, includes a digital-to-analog converter (DAC) 225, one or more frequency upconverting (UC) stages 230, and a power amplifier (PA) 235. The receiver 250, in turn, includes a first switching device SW1, a filter 255, a second switching device SW2, a low noise amplifier (LNA) 260, one or more frequency downconverting (DC) stages 265, and an analog-to-digital converter (ADC) 270.

With regard to uplink signal transmission, the modem 210 is configured to generate a digital transmit baseband signal DTXBB. The DAC 225 is configured to convert the digital transmit baseband signal DTXBB into an analog transmit baseband signal STXBB. The one or more frequency upconverting (UC) stages 230 is configured to frequency upconvert the analog transmit baseband signal S_{TXBB} into a transmit radio frequency (RF) signal S_{TXRF} using one or more transmit local oscillator (LO) signals S_{TXLO} generated by the LO 275, respectively. The PA 235 is configured to amplify the transmit RF signal S_{TXRF} to generate an uplink (UL) RF signal S_{UL}. The UL RF signal S_{UL} is provided to the antenna 245 via the antenna interface 240 (e.g., diplexer, duplexer, etc.) for wireless transmission to the base station (BS) 110.

With regard to signal reception, the antenna 245 pickups a wireless DL RF signal S_{DL} transmitted from the base station (BS) 110, which is provided to a pole terminal (p) of the first switching device SW1 via the antenna interface 240. The first switching device SW1 may be implemented structurally and/or functionally as a single pole double throw (SPDT) switching device. The first switching device SW1 includes a filter (f) terminal coupled to an input of the filter 255, and a bypass (b) terminal coupled to a corresponding bypass (b) terminal of the second switching device SW2. The second switching device SW2 may also be implemented as a SPDT switching device. The filter 255 includes an output coupled to a filter (f) terminal of the second switching device SW2. The second switching device SW2 includes a pole (p) coupled to an input of the LNA 260. The first and second switching devices SW1 and SW2 include control inputs configured to receive a bypass control signal from the modem 210.

If the modem 210 determines, based on UL transmission interval (slot) and DL reception (RX) interval (slot) scheduling, that the transmitter 220 is going to transmit a UL RF signal S_{UL} at the same time as the receiver is going to receive a DL RF signal S_{DL}, the modem 210 deasserts the bypass control signal to cause the first and second switching devices SW1-SW2 to couple their pole (p) terminals to their filter (f) terminals. In such case, the signal at the pole (p) of the first switching device SW1 includes the DL RF signal S_{DL} and a portion of the leaked US RF signal a₀*S_{UL} from the transmitter 220 leaked through the antenna interface 240, where a₀ represents the leakage coefficient of the antenna interface 240. Accordingly, with the first and second switching devices SW1-SW2 configured with their pole (p) terminals coupled to their filter (f) terminals, the filter 255 is enabled or is placed in the receive path to substantially block or filter out the leaked UL RF signal a₀*S_{UL} to substantially prevent the leaked RF signal a₀*S_{UL} from reaching the LNA 260. Accordingly, the signal provided to the input of the LNA 260 is substantially the DL RF signal S_{DL}.

If the modem 210 determines, based on UL TX slot and the DL RX slot scheduling, that the transmitter 220 is not going to transmit a UL RF signal S_{UL} during the same time interval as the receiver is going to receive a DL RF signal S_{DL}, the modem 210 asserts the bypass control signal to cause the first and second switching devices SW1-SW2 to couple their pole (p) terminals to their bypass (b) terminals. In such case, the signal at the pole (p) of the first switching device SW1 includes the DL RF signal S_{DL}, but not the leaked UL RF signal a₀*S_{UL} as it is not transmitted. Accordingly, with the first and second switching devices SW1-SW2 configured with their pole (p) terminals coupled to their bypass (b) terminals, the DL RF signal S_{DL} may be provided to the input of the LNA 260 while bypassing the filter 255. This avoids the insertion loss associated with the filter 255 to improve the sensitivity of the receiver 250, and increase the signal-to-noise ratio (SNR) of the received DL RF signal S_{DL}.

The LNA 260 is configured to amplify the received DL RF signal S_{DL} to generate a received amplified RF signal S_{RXRF}. The one or more frequency downconverting (DC) stages 265 is configured to frequency downconvert the received baseband signal S_{RXBB} into a received analog BB signal S_{RXBB} using one or more received local oscillator (LO) signals S_{RXLO} generated by the LO 275, respectively. The ADC 270 is configured to convert the received analog BB signal S_{RXBB} into a received digital BB signal D_{RXBB}. The modem 210 is configured to receive and process the received digital BB signal D_{RXBB} to recover/extract any data therein.

FIG. 2B illustrates a timing diagram related to an example operation of the transceiver 200 in accordance with another aspect of the disclosure. The horizontal axis of the timing diagram represents time. The vertical axis, from top to bottom, represents the state of the scheduled received (RX) slots, the state of the scheduled transmit (TX) slots, and the state of the filter bypass control signal.

In this example, there are five (5) RX slots each including a cyclic prefix (CP) interval (shaded) starting at time to. The receiver 250 is configured to receive a DL RF signal S_{DL} during each of the receive slots. Also, during time interval t₀-t₁, the transmitter 220 is in the process of transmitting a UL RF signal S_{UL} during a partially-shown TX slot. As the first RX slot overlaps with the partially-shown TX slot, which the modem 210 has knowledge of this based on a TX/RX slot schedule, the modem 210 has the filter bypass control signal deasserted during time interval t₀-t₁ so that the filter 255 protects the LNA 260 from the leaked transmit RF signal a₀*S_{UL}.

As indicated, at time t₁, the first TX slot ends. In response, the modem 210 asserts the filter bypass control signal at time t₃ (e.g., a time interval Δ_{TA} after the end of the first TX slot) to provide a safety margin between the end of the first TX slot and the bypassing of the filter 255. For example, the modem 210 may assert the filter bypass control signal during the CP interval of the next RX slot at time t₃ so as to avoid switching glitches during the data portion of the RX slot. As previously discussed, the asserted filter bypass control signal causes the received DL RF signal S_{DL} to be routed to the LNA 260 while bypassing the filter 255. Thus, the received DL RF signal S_{DL} is not subjected to the insertion loss of the filter 255 during the second and third RX slots; thereby improving the sensitivity of the receiver 250 and the SNR of the received DL RF signal S_{DL} during such RX slots.

Further, in accordance with this example, at time t₂, the modem 210 receives scheduling information (e.g., an uplink (UL) grant) of the next TX slot starting at time t₅. For example, the modem 210 may receive the TX slot scheduling information a certain time interval Δ_{TB} before the start of the next TX slot. In response, the modem 210 deasserts the filter bypass control signal at time t₄ a certain safety margin interval Δ_{TB} before the start of the TX slot at time t₅. Also, so as not to produce switching glitches during the data portion of the RX slot, the modem 210 may deassert the filter bypass control signal during the CP interval of the fourth RX slot. Accordingly, the modem 210 has the filter bypass control signal deasserted during TX slot between time interval t₅-t₆ so that the filter 255 protects the LNA 260 from the leaked transmit RF signal a₀*S_{UL}.

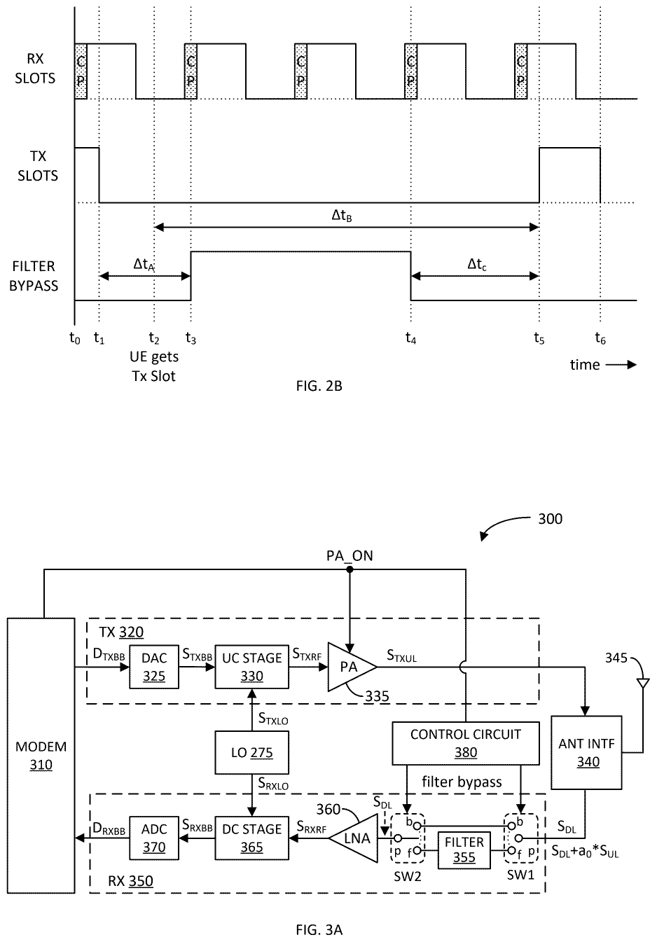

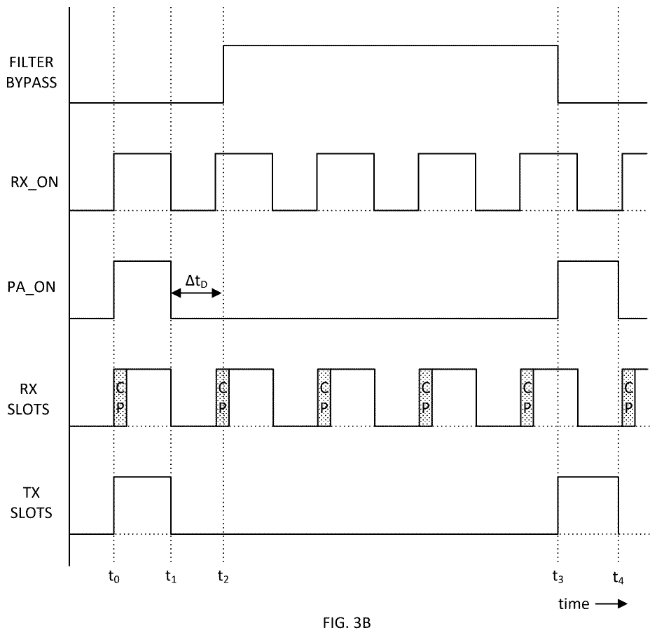

FIG. 3A illustrates a block diagram of another example transceiver 300 in accordance with another aspect of the disclosure. The transceiver 300 is similar to that of transceiver 200, and includes many of the same elements as indicated by the same reference numbers but with their most significant digit being a “3” instead of a “2” as in transceiver 200. The transceiver 300 differs from transceiver 200 in that the bypassing of the filter is a hardware approach instead of a software approach based on the TX/RX slot scheduling.

More specifically, the modem 310 is configured to generate a PA_ON signal to turn on the PA 355 or enable the transmitter 320 during a TX slot. The PA_ON signal may also be used to bypass or not to bypass the filter 355. In this regard, the transceiver 300 includes a control circuit 380 including an input configured to receive the PA_ON signal from the modem 310, and outputs coupled to the first and second switching devices SW1-SW2, respectively. Accordingly, in response to the modem 310 asserting the PA_ON signal, the control circuit 380 configures the first and second switching devices SW1-SW2 to couple their pole (p) terminals to their filter (f) terminals to enable or place the filter 355 within the received signal path. Thus, the filter 355 substantially blocks or filter outs the leaked transmit UL RF signal a₀*S_{UL} so as not to interfere with the amplification of the received DL RF signal S_{DL} by the LNA 360.

In response to the modem 310 deasserting the PA_ON at the end of the TX slot (e.g., to save power), the control circuit 380 may responsibly configure the first and second switching devices SW1-SW2 to couple their pole (p) terminals to their bypass (b) terminals to disable or place the filter 355 outside of the received signal path. Thus, the received DL RF signal S_{DL} is provided to the LNA 360 while bypassing the filter 355 so that the DL RF signal S_{DL} is not subjected to the insertion loss of the filter 355. This improves the sensitivity of the receiver 350 and the SNR of the received DL RF signal S_{DL}. The control circuit 380 may configure the switching devices SW1-SW2 to bypass the filter 355 a certain safety margin time interval after the deasserting of the PA_ON signal by the modem 310.

FIG. 3B illustrates a timing diagram related to an example operation of the transceiver 300 in accordance with another aspect of the disclosure. The horizonal axis represents time. The vertical axis represents, from top to bottom, the states of the filter bypass control signal, the receiver 350 (RX_ON), the PA_ON signal, RX slots, and the TX slots.

According to this example operation, the modem 310 asserts the PA_ON signal to enable the PA 335 or the transmitter 320 at the start of the first TX slot at time to. As the filter bypass control signal was deasserted prior to time to, the control circuit 380 maintains the filter bypass control signal deasserted to maintain the first and second switching devices SW1-SW2 coupling their pole (p) terminals to their filter (f) terminals to enable or place the filter 355 within the received signal path. Thus, the filter 355 substantially prevents the leaked transmit UL RF signal a₀*S_{UL} from reaching the LNA 360 so as not to interfere with the amplification of the received DL RF signal S_{DL} by the LNA 360.

When the modem 310 deasserts the PA_ON signal to turn off the PA 335 or the transmitter 320 at the end of the first TX slot at time t₁, the control circuit 380 may assert the filter bypass control signal a safety margin time interval Δt_{D} after the end of the TX slot. For example, the control circuit 380 may assert the filter bypass control signal at time t₂, which may coincide with the CP interval of the next RX slot to prevent switching glitches from impacting the receiver 350. As discussed, the filter bypass control signal being asserted configures the switching devices SW1-SW1 to couple their pole (p) terminals to their bypass (b) terminals to disable or bypass the filter 355 (e.g., placing the filter 355 outside of the received signal path). Thus, the received DL RF signal S_{DL} is provided to the LNA 360 while bypassing the filter 355 so that the signal S_{DL} is not subjected to the insertion loss of the filter 355. This improves the sensitivity of the receiver 350 and the SNR of the received DL RF signal S_{DL}.

As shown, the modem 310 may again assert the PA_ON signal to turn on the PA 335 or the transmitter 320 at the start of the next or second TX slot at time t₃. In response to the PA_ON signal being asserted, the control circuit 380 deasserts the filter bypass control signal to configure the first and second switching devices SW1-SW2 to couple their pole (p) terminals to their filter (f) terminals to enable or place the filter 355 within the received signal path. The control circuit 380 may maintain the filter bypass deasserted during the duration of the TX slot between times t₃-t₄. Thus, the filter 355 substantially prevents the leaked transmit UL RF signal a₀*S_{UL} from reaching the LNA 360 so as not to interfere with the amplification of the received DL RF signal S_{DL} by the LNA 360.

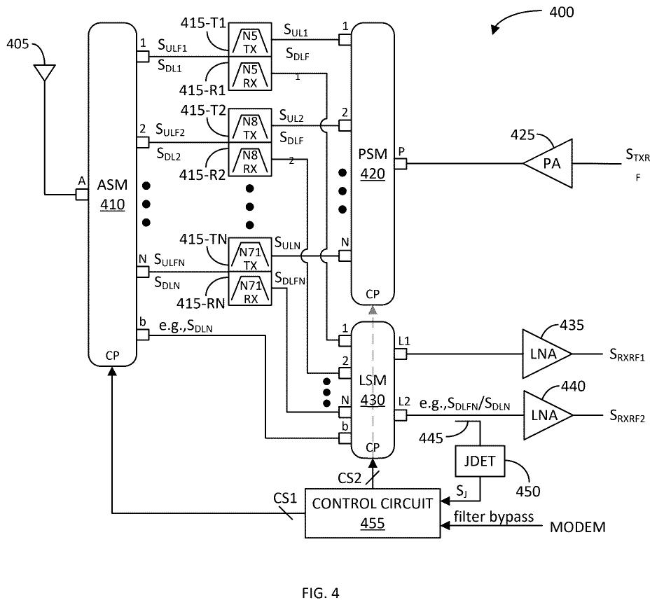

FIG. 4 illustrates a block diagram of an example transceiver radio frequency front-end (RFFE) 400 in accordance with another aspect of the disclosure. The transceiver RFFE 400 may be an example more detailed implementation of the front-end of the transceiver 200 where the modem 210 controls the bypassing of the filter 255 with software or, more specifically, based on the TX/RX slot scheduling.

In particular, the transceiver RFFE 400 includes an antenna 405 (e.g., an antenna array), an antenna switch matrix (ASM) 410, a set of one or more TX/RX filters 415-T1/415-R1 to 415-TN/415-RN (where N is an integer), a PA switch matrix (PSM) 420, a PA 425, an LNA switch matrix (LSM) 430, a first LNA 435, a second LNA 440, a coupler 445, a jammer detector (JDET) 450, and a control circuit 455.

The ASM 410 includes a port “A” coupled to the antenna 405, and a set of one or more ports 1-N coupled to the set of one or more TX/RX filters 415-T1/415-R1 to 415-TN/415-RN, respectively. The ASM 410 further includes a filter bypass (b) port coupled to a filter bypass (b) port of the LSM 430. Additionally, the ASM 410 includes a control port (CP) coupled to a first output of the control circuit 455 to receive a first control signal CS1.

The PSM 420 includes a set of one or more output ports 1-N coupled to the one or more TX filters 415-T1 to 415-TN, respectively. The PSM 420 includes a PA input port “P” coupled to an output of the PA 425. The PA 425 includes an input configured to receive a transmit RF signal S_{TXRF}. Additionally, the PSM 420 includes a control port (CP) coupled to a second output of the control circuit 455 to receive a second control signal CS2.

The LSM 430 includes a set of one or more input ports 1-N coupled to the set of one or more RX filters 415-R1 to 415-RN, respectively. The LSM 430 further includes first and second LNA output ports “L1” and “L2” coupled to inputs of the first and second LNA 435 and 440, respectively. The LSM 430 includes a control port (CP) coupled to the second output of the control circuit 455 to receive the second control signal CS2. The coupler 445 is coupled between the L2 output port of the input of the second LNA 440. The JDET 450 includes an input coupled to the coupler 445 and an output coupled to a first input of the control circuit 455. It shall be understood that another coupler and JDET may be coupled to the received signal path between output port L1 of the LSM 430 and the first LNA 435. The control circuit 455 includes a second input coupled to an output of a modem to receive a filter bypass control signal.

Considering some examples, the TX/RX filters 415-T1/415-R1 may be implemented as a band pass filter (BPF) with a passband compliant with 5G/6G NR “N5” communication band having frequency ranges 824-849 MHz/869-894 MHz (where MHz is mega Hertz). The TX/RX filters 415-T2/415-R2 may be implemented as a BPF with a passband compliant with 5G/6G NR “N8” communication bands having frequency ranges 880-915 MHz/925-960 MHz. And, the TX/RX filters 415-TN/415-RN may be implemented as a BPF with a passband compliant with 5G/6G NR “N71” communication bands having frequency ranges 663-698 MHz/617-652 MHz.

If the modem, based on TX/RX slot scheduling information, determines that there will be a simultaneous transmission of one or more of a set of UL RF signals S_{ULF1} to S_{ULFN} (e.g., S_{ULFN}) with the reception of a corresponding one or more of a set of DL RF signals S_{DL1} to S_{LDN} (e.g., S_{ULN}), the modem generates a deasserted filter bypass control signal. Considering the signals pertaining to port N as an example, based on the deasserted filter bypass control signal, the control circuit 455 generates the first control signal CS1 to cause the ASM 410 to couple the antenna port (A) to port N to output the DL RF signal S_{ULN} to the receive filter 415-RN. The receive filter 415-RN substantially removes the leaked UL RF signal a₀*S_{ULFN} from the DL RF signal S_{DLN} to generate a filtered DL RF signal S_{DLFN}. And, also based on the deasserted filter bypass control signal, the control circuit 455 generates the second control signal CS2 to cause the LSM 430 to couple the input port N to one of the LNA port L1 or L2 (e.g., L2) for providing the filtered DL RF signal S_{DLEN} to the second LNA 440. The second LNA 440 amplifies the filtered DL RF signal S_{DLEN} to generate a received RF signal S_{RXRF2} for further processing downstream (e.g., one or more frequency downconverters).

If the modem, based on TX/RX slot scheduling information, determines that there will be no simultaneous transmission of one or more of a set of UL RF signals S_{ULF1} to S_{ULFN} (e.g., S_{ULFN}) with the reception of one or more of a set of DL RF signals S_{DL1} to S_{LDN} (e.g., S_{ULN}), the modem generates an asserted filter bypass control signal. Again, considering the signals pertaining to port N as an example, based on the asserted filter bypass control signal, the control circuit 455 generates the first control signal CS1 to cause the ASM 410 to couple the antenna port (A) to the bypass port (b) to provide the unfiltered DL RF signal S_{DLN} to the bypass port (b) of the LSM 430. Accordingly, the unfiltered DL RF signal S_{DLN} is not subjected to the insertion loss of the filter 415-RN. And, also based on the asserted filter bypass control signal, the control circuit 455 generates the second control signal CS2 to cause the LSM 430 to couple the bypass port (b) to the second LNA output port L2 for providing the unfiltered DL RF signal S_{DLN} to the second LNA 440. The second LNA 440 amplifies the unfiltered DL RF signals S_{DLN} to generate a received RF signal S_{RXRF2} for further processing downstream (e.g., one or more frequency downconverters).

If the jammer detector 450 generates an asserted jammer detection signal Sy by detecting an out-of-band jammer in the unfiltered DL RF signal S_{DLN} via the coupler 445, the control circuit 455 responsibly generates the first control signal CS1 to cause the ASM 410 to couple the antenna port (A) to port N to route the DL RF signal S_{DLN} to receive filter 415-RN. The receive filter 415-RN substantially removes the out-of-band jammer from the DL RF signal S_{DLN} to generate a filtered DL RF signal S_{DLEN}. And, also based on the asserted jammer detection signal S_{J}, the control circuit 455 generates the second control signal CS2 to cause the LSM 430 to couple input port N to the LNA output port L2 for providing the filtered DL RF signal S_{DLEN} to the second LNA 440. The second LNA 440 amplifies the filtered DL RF signal S_{DLEN} to generate a received RF signal S_{RXRF2} for further processing downstream (e.g., one or more frequency downconverters).

Although the aforementioned operations of the transceiver 400 used DL RF signals S_{DLN}/S_{DLEN}/S_{ULFN} and the second LNA 440 as an example, it shall be understood that the aforementioned operations apply to the other signals S_{DL1}/S_{DLF1}/S_{ULF1}, S_{DL2}/S_{DLF2}/S_{ULF2}, etc. and the first LNA 435.

With regard to the transmission, the PSM 420 routes one or more of a set of unfiltered UL RF signals S_{UL1}-S_{ULN} from an output of the PA 425 to one or more of the set of TX filters 415-T1-415-N based on the second control signal CS2 generated by the control circuit 455, respectively. The one or more of the set of unfiltered UL RF signals S_{UL1}-S_{ULN} may be based on a transmit RF signal S_{TXRF} provided to the input of the PA 425. The corresponding one or more of the set of TX filters 415-T1 to 415-TN filter the one or more of the set of unfiltered UL RF signals S_{UL1}-S_{ULN} to generate the corresponding one or more of the filtered UL RF signal S_{ULF1} to S_{ULFN} for routing to the antenna 405 via the corresponding one or more of the ports 1-N and the antenna port (P) of the ASM 410 based on the first control signal CS1 generated by the control circuit 455.

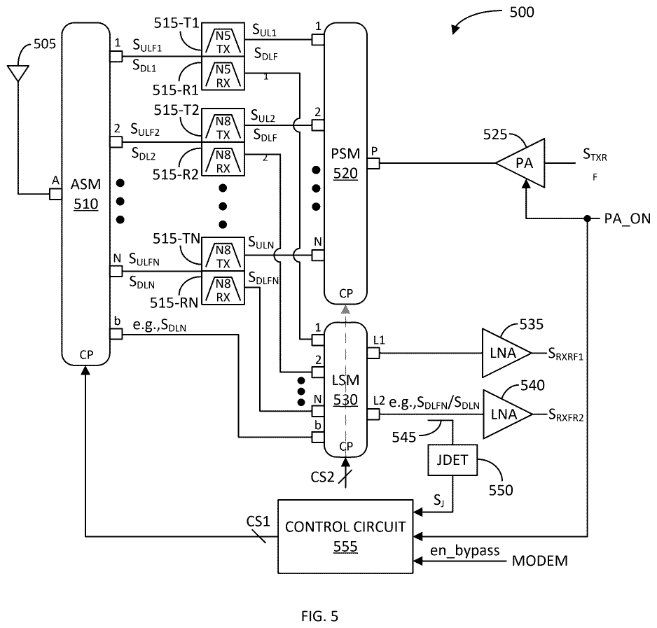

FIG. 5 illustrates a block diagram of another example transceiver radio frequency front-end (RFFE) 500 in accordance with another aspect of the disclosure. The transceiver RFFE 500 is similar to transceiver RFFE 400 previously discussed including many of the same elements as indicated by the same reference numbers but with their most significant digit being a “5” instead of a “4” as in transceiver RFFE 400. The transceiver RFFE 500 differs from the transceiver RFFE 400 in that the PA or transmitter enable control signal PA_ON takes the place of the filter bypass control signal.

In this example, the modem provides an enable bypass (en_bypass) signal to the control circuit 555 to enable or disable the filter bypassing. For example, the modem may enable the bypassing if the channel environment is good enough to do the bypass. If the en_bypass signal is deasserted (e.g., the channel environment may not be that good), the control circuit 555 does not perform the filter bypassing regardless the state of the PA_ON control signal. If the en_bypass signal is asserted (e.g., the channel environment may be good enough to perform the filter bypass), the control circuit 555, based on an asserted PA_ON control signal, generates the first control signal CS1 to cause the ASM 510 to couple the antenna port (A) to port N to output the DL RF signal S_{ULN} to the receive filter 515-RN. The receive filter 515-RN substantially removes the leaked UL RF signal a₀*S_{ULFN} from the DL RF signal S_{DLN} to generate a filtered DL RF signal S_{DLFN}. And, also based on the deasserted filter bypass control signal, the control circuit 555 generates the second control signal CS2 to cause the LSM 530 to couple the input port N to LNA output port L2 for providing the filtered DL RF signal S_{DLEN} to the second LNA 540. The second LNA 540 amplifies the filtered DL RF signal S_{DLEN} to generate a received RF signal S_{RXRF2} for further processing downstream (e.g., one or more frequency downconverters).

Based on a deasserted PA_ON control signal, the control circuit 555 generates the first control signal CS1 to cause the ASM 510 to couple the antenna port (A) to the bypass port (b) to provide the unfiltered DL RF signal S_{DLN} to the bypass port (b) of the LSM 530. Accordingly, the unfiltered DL RF signal S_{DLN} is not subjected to the insertion loss of the filter 515-RN. And, also based on the asserted filter bypass control signal, the control circuit 555 generates the second control signal CS2 to cause the LSM 530 to couple the bypass port (b) to the second LNA output port L2 for providing the unfiltered DL RF signal S_{DLN} to the second LNA 540. The second LNA 540 amplifies the unfiltered DL RF signals S_{DLN} to generate a received RF signal S_{RXRF2} for further processing downstream (e.g., one or more frequency downconverters).

If the jammer detector 550 generates an asserted jammer detection signal Sy by detecting an out-of-band jammer in the unfiltered DL RF signal S_{DLN} via the coupler 545, the control circuit 555 responsibly generates the first control signal CS1 to cause the ASM 510 to couple the antenna port (A) to port N to route the DL RF signal S_{DLN} to receive filter 515-RN. The receive filter 515-RN substantially removes the out-of-band jammer from the DL RF signal S_{DLN} to generate a filtered DL RF signal S_{DLFN}. And, also based on the asserted jammer detection signal S_{J}, the control circuit 555 generates the second control signal CS2 to cause the LSM 530 to couple the input port N to the LNA output port L2 for providing the filtered DL RF signal S_{DLEN} to the second LNA 540. The second LNA 540 amplifies the filtered DL RF signal S_{DLEN} to generate a received RF signal S_{RXRF2} for further processing downstream (e.g., one or more frequency downconverters).

Although the aforementioned operations of the transceiver 500 used DL RF signals S_{DLN}/S_{DLEN}/S_{ULFN} and the second LNA 540 as an example, it shall be understood that the aforementioned operations apply to the other signals S_{DL1}/S_{DLF1}/S_{ULF1}, S_{DL2}/S_{DLF2}/S_{ULF2}, etc. and the first LNA 535.

With regard to the transmission, the PSM 520 routes one or more of a set of unfiltered UL RF signals S_{UL1}-S_{ULN} from an output of the PA 525 (enabled by the PA_ON control signal) to one or more the set of TX filters 415-T1-415-N based on the second control signal CS2 generated by the control circuit 555, respectively. The one or more of the set of unfiltered UL RF signals S_{UL1}-S_{ULN} may be based on a transmit RF signal S_{TXRF} provided to the input of the PA 525. The corresponding one or more of the set of TX filters 515-T1 to 515-TN filter the one or more of the set of unfiltered UL RF signals S_{UL1}-S_{ULN} to generate one or more of the filtered UL RF signal S_{ULF1} to S_{ULFN} for routing to the antenna 505 via the corresponding one or more of the ports 1-N and the antenna port (P) of the ASM 510 based on the first control signal CS1 generated by the control circuit 555.

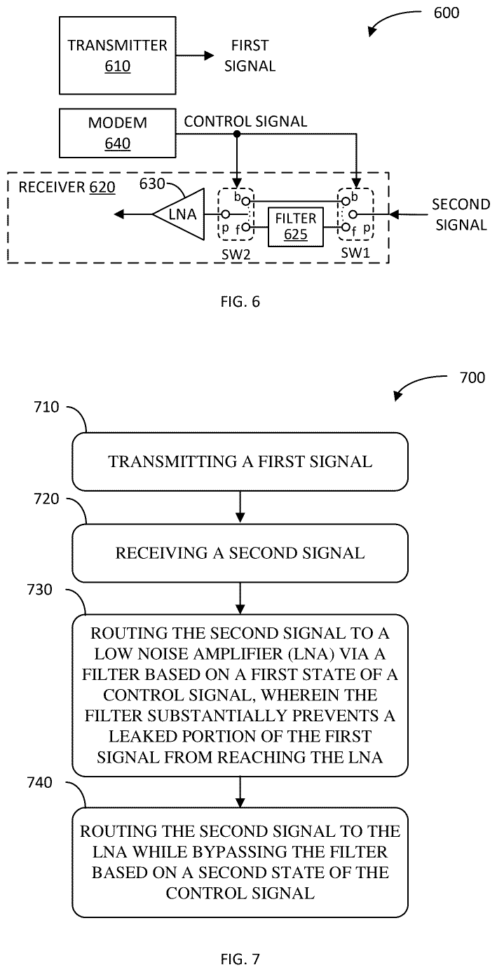

FIG. 6 illustrates a block diagram of an example transceiver 600 in accordance with another aspect of the disclosure. The transceiver 600 includes a transmitter 610 configured to transmit a first signal, a receiver 620 configured to receive a second signal, and a modem 640 configured to generate a control signal. The receiver 620, in turn, includes a filter 625; a low noise amplifier (LNA) 630; a set of one or more switching devices SW1-SW2 configured to: route the second signal to the LNA 630 via the filter 625 based on a first state of the control signal, or route the second signal to the LNA 630 while bypassing the filter 625 based on a second state of the control signal based on scheduling information associated with the transmission of the first signal.

FIG. 7 illustrates a flow diagram of an example method 700 of receiving signal in accordance with another aspect of the disclosure. The method 700 includes transmitting a first signal (block 710). Examples of means for transmitting a first signal include any of the transmitters and/or components thereof described herein. The method 700 further includes receiving a second signal (block 720). Examples of means for receiving a second signal include any of the receivers and/or components thereof described herein.

Additionally, the method 700 includes routing the second signal to a low noise amplifier (LNA) via a filter based on a first state of a control signal, wherein the filter substantially prevents a leaked portion of the first signal from reaching the LNA (block 730). Examples of means for routing the second signal to a low noise amplifier (LNA) via a filter based on a first state of a control signal include any one of the switching devices, antenna switch matrices (ASMs), and LNA switch matrices (LSM) described herein. Further, the method 700 includes routing the second signal to the LNA while bypassing the filter based on a second state of the control signal (block 740). Examples of means for routing the second signal to the LNA while bypassing the filter based on a second state of the control signal include any one of the switching devices, antenna switch matrices (ASMs), and LNA switch matrices (LSM) described herein.

The following provides an overview of aspects of the present disclosure:

Aspect 1: A transceiver, comprising: a transmitter configured to transmit a first signal; a receiver configured to receive a second signal, wherein the receiver comprises: a filter; a low noise amplifier (LNA); a set of one or more switching devices configured to: route the second signal to the LNA via the filter based on a first state of a control signal, wherein the filter substantially prevents a leaked portion of the first signal from reaching the LNA; or route the second signal to the LNA while bypassing the filter based on a second state of the control signal; and a modem configured to generate the control signal based on scheduling information associated with the transmission of the first signal.

Aspect 2: The transceiver of aspect 1, wherein the modem is configured to generate the control signal with the first state based on the transmitter transmitting the first signal simultaneous with the receiver receiving the second signal.

Aspect 3: The transceiver of aspect 1 or 2, wherein the modem is configured to generate the control signal with the second state based on the transmitter not transmitting the first signal simultaneous with the receiver receiving the second signal.

Aspect 4: The transceiver of any one of aspects 1-3, wherein the modem is configured to generate the control signal with the second state based on a scheduled transmit slot associated with the transmitter transmitting the first signal not overlapping in time with a scheduled receive slot associated with the receiver receiving the second signal.

Aspect 5: The transceiver of any one of aspects 1-4, wherein the modem is configured to generate the control signal with the first state based on a scheduled transmit slot associated with the transmitter transmitting the first signal overlapping in time with a scheduled receive slot associated with the receiver receiving the second signal.

Aspect 6: The transceiver of aspect 5, wherein the modem is configured to generate the control signal with the first state a time interval prior to the scheduled transmit slot.

Aspect 7: The transceiver of aspect 5 or 6, wherein the modem is configured to generate the control signal with the second state a time interval after the scheduled transmit slot.

Aspect 8: The transceiver of any one of aspects 1-7, wherein the control signal is configured to enable the transmitter for transmitting the first signal.

Aspect 9: The transceiver of any one of aspects 1-8, wherein the transmitter comprises a power amplifier (PA) configured to amplify a third signal to generate the first signal, wherein the control signal is configured to enable the PA.

Aspect 10: The transceiver of any one of aspects 1-9, wherein the set of one or more switching devices is configured to route the second signal to the LNA via the filter regardless of the state of the control signal in response to a deasserted state of an enable bypass signal generated by the modem.

Aspect 11: The transceiver of any one of aspects 1-10, wherein the transmitter is configured to transmit the first signal and the receiver is configured to receive the second signal in accordance with a frequency division duplexing (FDD).

Aspect 12: The transceiver of any one of aspects 1-11, wherein the receiver further comprises a jammer detector configured to generate a jammer detection signal, wherein the set of one or more switching devices are configured to: route the second signal to the LNA via the filter based on an asserted state of the jammer detection signal; or route the second signal to the LNA while bypassing the filter based on a deasserted state of the jammer detection signal.

Aspect 13: A method, comprising: transmitting a first signal; receiving a second signal; routing the second signal to a low noise amplifier (LNA) via a filter based on a first state of a control signal, wherein the filter substantially prevents a leaked portion of the first signal from reaching the LNA; or routing the second signal to the LNA while bypassing the filter based on a second state of the control signal.

Aspect 14: The method of aspect 13, further comprising generating the control signal with the first state when the transmitting of the first signal occurs simultaneous with the receiving of the second signal.

Aspect 15: The method of aspect 13 or 14, further comprising generating the control signal with the second state when the transmitting of the first signal does not occur simultaneous with the receiving of the second signal.

Aspect 16: The method of any one of aspects 13-15, further comprising generating the control signal based on scheduling information associated with transmitting the first signal and receiving the second signal.

Aspect 17: The method of any one of aspects 13-16, further comprising generating the control signal with the first state to enable the transmitting of the first signal.

Aspect 18: The method of any one of aspects 13-17, wherein transmitting the first signal and receiving the second signal is in accordance with frequency division duplexing (FDD).

Aspect 19: The method of any one of aspects 13-18, further comprising: detecting a jammer; and routing the second signal to the LNA via the filter in response to detecting the jammer.

Aspect 20: A transceiver, comprising: means for transmitting a first signal; means for receiving a second signal; means for routing the second signal to a low noise amplifier (LNA) via a filter based on a first state of a control signal, wherein the filter substantially prevents a leaked portion of the first signal from reaching the LNA; or means for routing the second signal to the LNA while bypassing the filter based on a second state of the control signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. A transceiver, comprising:
a transmitter configured to transmit a first signal;
a receiver configured to receive a second signal, wherein the receiver comprises:
a filter;
a low noise amplifier (LNA);
a set of one or more switching devices configured to:
route the second signal to the LNA via the filter based on a first state of a control signal, wherein the filter substantially prevents a leaked portion of the first signal from reaching the LNA; or
route the second signal to the LNA while bypassing the filter based on a second state of the control signal; and
a modem configured to generate the control signal based on scheduling information associated with the transmission of the first signal.

2. The transceiver of claim 1, wherein the modem is configured to generate the control signal with the first state based on the transmitter transmitting the first signal simultaneous with the receiver receiving the second signal.

3. The transceiver of claim 1, wherein the modem is configured to generate the control signal with the second state based on the transmitter not transmitting the first signal simultaneous with the receiver receiving the second signal.

4. The transceiver of claim 1, wherein the modem is configured to generate the control signal with the second state based on a scheduled transmit slot associated with the transmitter transmitting the first signal not overlapping in time with a scheduled receive slot associated with the receiver receiving the second signal.

5. The transceiver of claim 1, wherein the modem is configured to generate the control signal with the first state based on a scheduled transmit slot associated with the transmitter transmitting the first signal overlapping in time with a scheduled receive slot associated with the receiver receiving the second signal.

6. The transceiver of claim 5, wherein the modem is configured to generate the control signal with the first state a time interval prior to the scheduled transmit slot.

7. The transceiver of claim 5, wherein the modem is configured to generate the control signal with the second state a time interval after the scheduled transmit slot.

8. The transceiver of claim 1, wherein the control signal with the first state is configured to enable the transmitter.

9. The transceiver of claim 1, wherein the transmitter comprises a power amplifier (PA) configured to amplify a third signal to generate the first signal, wherein the control signal with the first state is configured to enable the PA.

10. The transceiver of claim 1, wherein the set of one or more switching devices is configured to route the second signal to the LNA via the filter regardless of the state of the control signal in response to a deasserted state of an enable bypass signal generated by the modem.

11. The transceiver of claim 1, wherein the transmitter is configured to transmit the first signal and the receiver is configured to receive the second signal in accordance with frequency division duplexing (FDD).

12. The transceiver of claim 1, wherein the receiver further comprises a jammer detector configured to generate a jammer detection signal, wherein the set of one or more switching devices are configured to:
route the second signal to the LNA via the filter based on an asserted state of the jammer detection signal; or
route the second signal to the LNA while bypassing the filter based on a deasserted state of the jammer detection signal.

13. A method, comprising:
transmitting a first signal;
receiving a second signal;
routing the second signal to a low noise amplifier (LNA) via a filter based on a first state of a control signal, wherein the filter substantially prevents a leaked portion of the first signal from reaching the LNA; or
routing the second signal to the LNA while bypassing the filter based on a second state of the control signal.

14. The method of claim 13, further comprising generating the control signal with the first state when the transmitting of the first signal occurs simultaneous with the receiving of the second signal.

15. The method of claim 13, further comprising generating the control signal with the second state when the transmitting of the first signal does not occur simultaneous with the receiving of the second signal.

16. The method of claim 13, further comprising generating the control signal based on scheduling information associated with transmitting the first signal and receiving the second signal.

17. The method of claim 13, further comprising generating the control signal with the first state to enable the transmitting of the first signal.

18. The method of claim 13, wherein transmitting the first signal and receiving the second signal is in accordance with frequency division duplexing (FDD).

19. The method of claim 13, further comprising:
detecting a jammer; and
routing the second signal to the LNA via the filter in response to detecting the jammer.

20. A transceiver, comprising:
means for transmitting a first signal;
means for receiving a second signal;
means for routing the second signal to a low noise amplifier (LNA) via a filter based on a first state of a control signal, wherein the filter substantially prevents a leaked portion of the first signal from reaching the LNA; or
means for routing the second signal to the LNA while bypassing the filter based on a second state of the control signal.
